(19) United States
(12) Patent Application Publication
(10) Pub. No.: US 2017/0133307 A1
(43) Pub. Date: May 11, 2017

(54) PACKAGING SUBSTRATE FOR SEMICONDUCTOR DEVICES, CORRESPONDING DEVICE AND METHOD

(71) Applicant: STMicroelectronics S.r.l., Agrate Brianza (IT)

(72) Inventor: Federico Giovanni Ziglioli, Pozzo d'Adda (IT)

(73) Assignee: STMicroelectronics S.r.l., Agrate Brianza (IT)

(21) Appl. No.: 15/159,212

(22) Filed: May 19, 2016

(30) Foreign Application Priority Data
Nov. 10, 2015 (IT) 102015000071060

(51) Int. Cl. H01L 23/498; H01L 21/48; H01L 23/00

(52) U.S. Cl. CPC H01L 23/49838; H01L 24/49; H01L 21/4846; H01L 24/32; H01L 24/73; H01L 2224/32225; H01L 2224/48091; H01L 2224/48106; H01L 2224/48227; H01L 2924/14; H01L 2924/01079; H01L 2924/01078; H01L 2924/01047; H01L 2924/01028; H01L 2924/01029; H01L 2924/01013; H01L 2924/01006; H01L 2924/01044; H01L 2924/0538; H01L 2924/07025; H01L 2924/06; H01L 2924/15747

(57) ABSTRACT

A substrate for mounting a semiconductor device includes an insulating layer having first and second opposed surfaces defining a thickness. First and second electrically conductive lands are included in the insulating layer. The first electrically conductive lands extend through the whole thickness of the insulating layer and are exposed on both the first and second opposed surfaces. The second electrically conductive lands have a thickness less than the thickness of the insulating layer and are exposed only at the first surface. Electrically conductive lines at the first surface of the insulating layer couple certain ones of the first electrically conductive lands with certain ones of the second electrically conductive lands. The semiconductor device is mounted to the first surface of the insulating layer. Wire bonding may be used to electrically coupling the semiconductor device to certain ones of the first and second lands.

### PRIORITY CLAIM

This application claims priority from Italian Application for Patent No. 102015000071060 filed Nov. 10, 2015, the disclosure of which is incorporated by reference.

### TECHNICAL FIELD

The description relates to packaging substrates for semiconductor devices.

One or more embodiments may be applied e.g. to integrated circuits (ICs).

### BACKGROUND

Due to the continuing growth of the semiconductor device industry, a steady demand exists for improved packaging options, e.g. solutions which may permit using a same substrate/lead frame for different dice with specific size and a wider range of input/output (I/O) connections.

### SUMMARY

According to one or more embodiments, a packaging substrate for semiconductor devices is provided.

One or more embodiments may also relate to a corresponding device (e.g. an integrated circuit) as well as to a corresponding method.

One or more embodiments may provide a package which includes metal lands with two different thicknesses; one type of land with two faces exposed with respect to the insulating compound layer, the other type having only one face exposed with respect to the insulating layer.

In one or more embodiments, a printed metal track (conductive line) may connect a top surface of two or more metal lands and a wire bonding, thus creating an interconnection between the die and the metal track.

One or more embodiments may offer one or more of the following advantages: a need no longer exists for a specific lead frame/substrate for each device; wire bonding can be provided on a standard lead finishing; a high flexibility if provided in terms of routing solutions; and applicability to leaded packages with dedicated pre-molded carriers.

In an embodiment, a substrate for mounting semiconductor devices comprises: an electrically insulating layer having first and second opposed surfaces, the electrically insulating layer having a thickness between said first and second opposed surfaces, the substrate including first and second electrically conductive lands in said electrically insulating layer, wherein: said first lands extend through a whole thickness of said electrically insulating layer and are exposed on both the first and second opposed surfaces of the electrically insulating layer, and said second lands have a thickness less than the thickness of the electrically insulating layer and are exposed only at the first surface of the electrically insulating layer.

In an embodiment, a semiconductor device includes: a substrate including an electrically insulating layer having first and second opposed surfaces, the electrically insulating layer having a thickness between said first and second opposed surfaces, the substrate including first and second electrically conductive lands in said electrically insulating layer, wherein: said first lands extend through a whole thickness of said electrically insulating layer and are exposed on both the first and second opposed surfaces of the electrically insulating layer, and said second lands have a thickness less than the thickness of the electrically insulating layer and are exposed only at the first surface of the electrically insulating layer; at least one semiconductor die mounted on said first surface of the electrically insulating layer, and wire bonding electrically coupling said at least one semiconductor die with selected ones of said first and second lands.

In an embodiment, a method comprises: etching a first surface of an electrically conductive laminar carrier to produce raised portions corresponding to locations of first lands and produce a recessed surface, further etching said recessed surface of said laminar carrier to produce indented portions between raised portion corresponding to locations of second lands, molding onto said first surface of said laminar carrier an electrically insulating molding material that penetrates into said indented portions and covers said recessed surface of said laminar carrier at said raised portions, and removing said electrically conductive laminar carrier at a second surface opposite the first surface to expose the molding compound which penetrated into said indented portions.

In an embodiment, a method comprises: growing first and second electrically conductive formations on a first surface of a sacrificial carrier layer, wherein said first electrically conductive formations correspond to locations of first lands, and wherein said second electrically conductive formations correspond to locations of seconds lands, applying a mask material on said first surface of said sacrificial carrier layer to penetrate into indented portions between said second electrically conductive formations and further covers said second electrically conductive formations while leaving said first electrically conductive formations uncovered, further growing electrically conductive material onto said uncovered first electrically conductive formations, molding onto said first surface of said sacrificial carrier layer an electrically insulating molding material that fills space between the further grown electrically conductive material, and removing the sacrificial carrier layer.

### BRIEF DESCRIPTION OF THE DRAWINGS

One or more embodiments will now be described, by way of example only, with reference to the annexed figures, wherein:

FIG. 1, including portions a) to e), show process steps;

FIG. 2, including portions a) to f), show process steps;

FIG. 3, including portions a) to c), show process steps;

FIGS. 4 and 5 are plan views of semiconductor devices; and

FIGS. 6 and 7 are further plan views exemplary of possible substrate customization.

It will be appreciated that for the sake of simplicity of representation the various figures may not be drawn to a same scale.

### DETAILED DESCRIPTION

In the ensuing description, one or more specific details are illustrated, aimed at providing an in-depth understanding of examples of embodiments. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment. Moreover, particular conformations, structures, or characteristics may be combined in any adequate way in one or more embodiments.

The references used herein are provided merely for convenience and hence do not define the extent of protection or the scope of the embodiments.

One or more embodiments may take advantage of the availability of metal ink printers (e.g. aerosol ink jet printers).

In the area of electronics these printers are primarily used to produce metal tracks (that is, conductive lines) on substrates such as e.g. printed circuit boards—PCBs.

Aerosol jet systems may reliably produce ultra-fine feature circuitry beyond the capabilities of e.g. thick-film and ink jet processes. For instance, many materials can be “written” with a resolution of down to 20 μm, with a total length of each interconnect of e.g. 1.5 mm with a throughput for a single nozzle reaching up to 5,000 interconnects per hour. An aerosol jet print head is highly scalable and may support e.g. 2, 3, 5, or more nozzles at a time, pitch dependent, enabling throughputs as high as 25,000 interconnects per hour or more.

Just by way of example, materials adapted to be printed may include metals (e.g. gold, platinum, silver, nickel, copper, aluminum), resistive ink materials (e.g. carbon, ruthenate), non-metallic conductors (e.g. single wall carbon nanotubes, multi wall carbon nanotubes, PEDOT:PSS), dielectrics and adhesive materials (e.g. polyimide, polyvinylpyrrolidone (PVP), Teon AF, SU-8 Adhesives, opaque coatings, UV adhesives UV acrylics), semiconductors (e.g. organic semiconductors), solvents, acids and bases, photo- and etch-resists, DNA, proteins, enzymes.

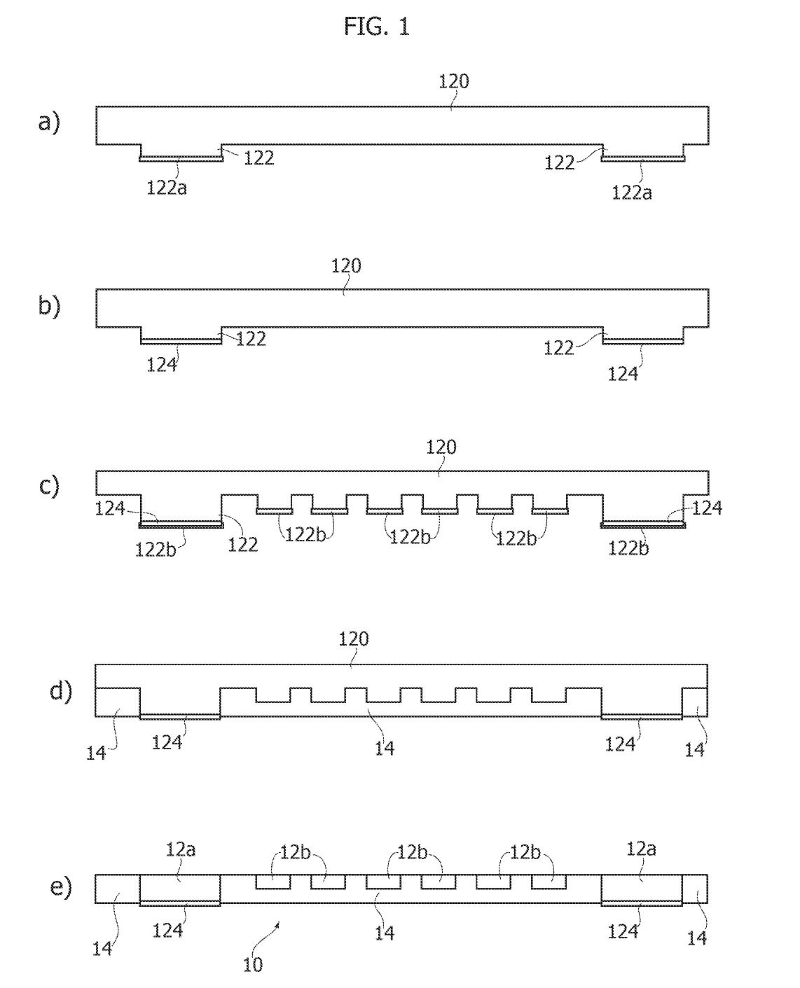

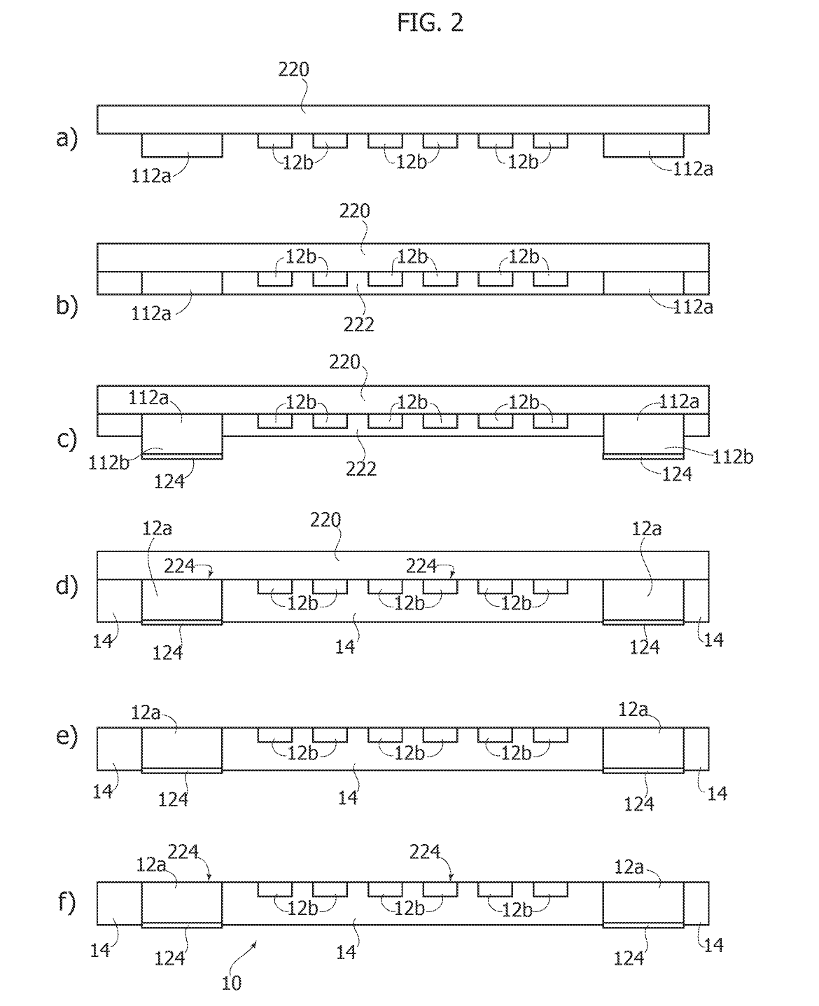

The diagrams of FIGS. 1 and 2 are exemplary of ways of producing a package substrate 10 where the substrate includes two types of electrically conductive (e.g. metal) portions or “lands” with two different thicknesses:
one type of land, 12a, is thick enough to have two opposed faces which are exposed on both surfaces (upper and lower, in the figures) of an insulating compound layer 14,
the other type of land, 12b, is less thick and thus has only one face exposed on one surface (e.g. the upper one in the figures) of the insulating compound layer 14.

The sequence of steps a) to e) of FIG. 1 is exemplary of an etching-based process for producing such a substrate, the process including e.g.:
step a) a first etching of a laminar e.g. copper carrier 120 while covering certain portions of one (here, lower) side of the carrier with a resist layer 122a so that raised portions 122 intended to form “precursors” of the first lands 12a remain at that side as a result of etching;
step b) forming leads 124, e.g. by plating the surfaces of the raised portions 122;
step c) a second etching of the copper carrier 120 by covering with a resist layer 122b the plated surfaces 124 of the raised portions 122 as well as selected areas of the carrier 120 so that indented portions are formed in the carrier 120 between the areas selectively covered by the resist layer 122b;
step d) pre-molding onto the “sculptured” (here, lower) surface of the carrier 120 an electrically insulating package molding compound 14 (of any known type suitable for that purpose) so that the compound 14 covers the carrier surface between the raised portions 122 (first lands 12a) while also penetrating into the indented portions formed between the areas previously covered by the resist layer 122b (which may be removed before molding the package molding compound 14 onto the carrier 120);
step e) removing (e.g. by grinding) the carrier material at the opposed (here, upper) side of the carrier 120 for a thickness enough to expose the (solidified) molding compound 14 at the indented portions.

As a result, the plated surfaces 124 of the raised portions 122 will form—at the first lands 12a—e.g. an array of substrate pads (e.g. plated pads) 124 at one (here lower) surface or side of the resulting substrate, while the remainder portions of the carrier 120 selectively covered by the resist layer 122b (see portion c) of FIG. 1) will form e.g. an array of second lands 12b at the other (here upper) surface or side of the resulting substrate, namely an e.g. matrix array of bonding pads mutually isolated by the compound 14 penetrated into the indented portions therebetween.

Technologies and apparatus for use in performing each of the steps a) to e) of FIG. 1 are known in the art, which makes it unnecessary to provide a more detailed description herein.

The sequence of steps a) to f) of FIG. 2 is exemplary of a growth-based process for producing a similar substrate, the process including e.g.:
step a) a first growing (e.g. chemically) of electrically conductive (e.g. copper) formations 112a and 12b on one side (here lower) of a “sacrificial” carrier 220 of e.g. inox steel (e.g. 100 micron-100.10−6 m) or other suitable metal alloys with the formations 12b (e.g. already the second lands) at least slightly thinner than the formations 112a (these latter being intended to form “precursors” of the first lands 12a);
step b) masking with a mask material 222 the side of the carrier 220 onto which the formations 112a, 12b have been grown with a masking material of a thickness enough to cover the formations 12b while leaving the formations 112a uncovered;
step c) a second growing (e.g. chemically) of electrically conductive (e.g. copper) material 112b onto the formations 112a in order to complete the first lands 12a by forming leads 124 e.g. by plating at the surfaces of the first lands 12a thus completed;
step d) molding onto the “sculptured” (here again, lower) surface of the carrier 220, optionally after removing the mask material 222, an electrically insulating package molding compound 14 (of any known type suitable for that purpose) so that the compound 14 covers the carrier surface between the raised portions (first lands 12a) while also penetrating into the indented portions are formed between the second lands 12b;
step e) removing (e.g. by peeling) the sacrificial carrier material 220.

As a result, the plated surfaces 124 of the raised portions 122 will form—at the first lands 12a—e.g. an array of substrate pads (e.g. plated pads) 124 at one (here lower) surface or side of the resulting substrate, while the second lands 12b at the other (here upper) surface of the resulting substrate will form a e.g. matrix array of bonding pads mutually isolated by the compound 14 penetrated into the indented portions therebetween.

A final step f) of top surface finishing may then be performed as schematically indicated at 224. It will be understood that a same top surface finishing step may be performed after the step e) of FIG. 1.

Here again, technologies and apparatus for use in performing each of the steps a) to f) of FIG. 2 are known in the art, which makes it unnecessary to provide a more detailed description herein.

In one or more embodiments, both processes as exemplified in FIGS. 1 and 2 may make it possible to produce a substrate for mounting semiconductor devices, the substrate including an electrically insulating layer 14 having first and second opposed surfaces (upper and lower, in the figures), the electrically insulating layer 14 having a thickness between the first and second opposed surfaces, the substrate including (e.g. an array of) first electrically conductive lands 12a and (e.g. an array of) second electrically conductive lands 12b (formed e.g. embedded) in the electrically insulating layer 14, wherein:
the first lands 12a extend through the whole thickness of the electrically insulating layer 14 and are exposed on both the first and second opposed surfaces of the electrically insulating layer 14, and
the second lands 12b have a thickness less than the thickness of the electrically insulating layer 14 and are exposed only at the first (e.g. upper) surface of the electrically insulating layer 14.

In one or more embodiments, the first lands 12a and the second lands 12b may be exposed to the first surface of the electrically insulating layer 14 flush therewith: see e.g. FIG. 1, portion e) or FIG. 2, portions e) and f).

In one or more embodiments, the first lands 12a may include contact pads 124 at the second surface of the electrically insulating layer 14.

In one or more embodiments as exemplified in FIG. 1, producing a substrate 10 as exemplified in the foregoing may include:
etching a surface of an electrically conductive laminar carrier (e.g. 120) by producing raised portions to provide said first lands (e.g. 12a),
further etching said surface of said laminar carrier to provide indented portions in said carrier between said second lands (e.g. 12b),
molding onto said surface of said laminar carrier an electrically insulating molding material (e.g. 14), whereby the molding material covers said surface of said laminar carrier between said raised portions while also penetrating into said indented portions, and
removing said electrically conductive laminar carrier material at the surface opposed said etched surface to expose the molding compound at said indented portions.

In one or more embodiments as exemplified in FIG. 2, producing a substrate 10 as exemplified in the foregoing may include:
growing first and second electrically conductive formations on a surface of a sacrificial carrier layer (e.g. 220), said second electrically conductive formations forming said seconds lands (e.g. 12b),
applying a mask material (e.g. 222) on said surface of said sacrificial carrier layer to cover said second formations while leaving said first formations uncovered,
further growing electrically conductive material onto said first formations to complete said first lands (e.g. 12a),
molding onto said surface of said sacrificial carrier layer an electrically insulating molding material (e.g. 14) to cover said sacrificial carrier layer between said first lands and penetrate into the indented portions between said second lands, and
removing the sacrificial carrier layer.

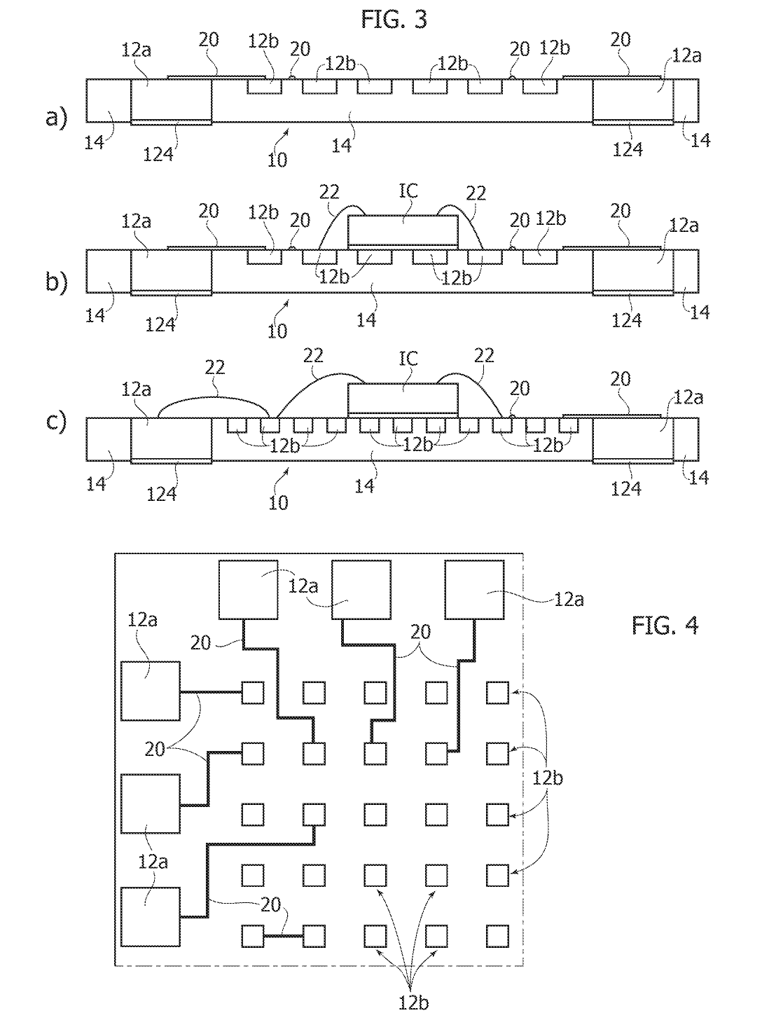

Whatever the approach adopted, in one or more embodiments, the structures obtained as a result of the steps exemplified in FIG. 1 or FIG. 2 may be subjected to further steps as exemplified in FIG. 3 aiming at producing a package with a substrate 10 where e.g. metal tracks 20 (electrically conductive lines) may be printed, possibly by ink jet/aerosol ink jet printing, to connect at their top surfaces (e.g. at the upper surface of the insulating layer 14) one more lands 12a, 12b with wire bonding 22 to provide electrical connection between a semiconductor device (e.g. an integrated circuit die IC) and such a conductive lines or tracks.

It will be appreciated that, in order to highlight the intrinsic flexibility of one or more embodiments, step c) of FIG. 3 deliberately shows a different pattern of second lands 12b with respect to portion b).

One or more embodiments may thus include electrically conductive lines 20 at the first (e.g. upper) surface of the electrically insulating layer 14 for coupling selected ones of the first lands 12a with selected ones of the second lands 12b.

One or more embodiments may thus provide a semiconductor device including a substrate as exemplified herein, with one or more semiconductor dice IC on the first surface of the electrically insulating layer 14, wire bonding 22 being provided for electrically coupling the semiconductor die/dice IC with selected ones of the first lands 12a and/or second lands 12b.

In one or more embodiments, ink printed tracks or lines 20 may have a width of 50-100 micron (50-100.10⁻⁶ m) with multi-layer thickness of 10-20 micron (10-20.10⁻⁶ m), e.g. for those applications where lower resistivity may be desirable for a specific I/O, with a wire adapted to bridge from different pads (with proper dimensions).

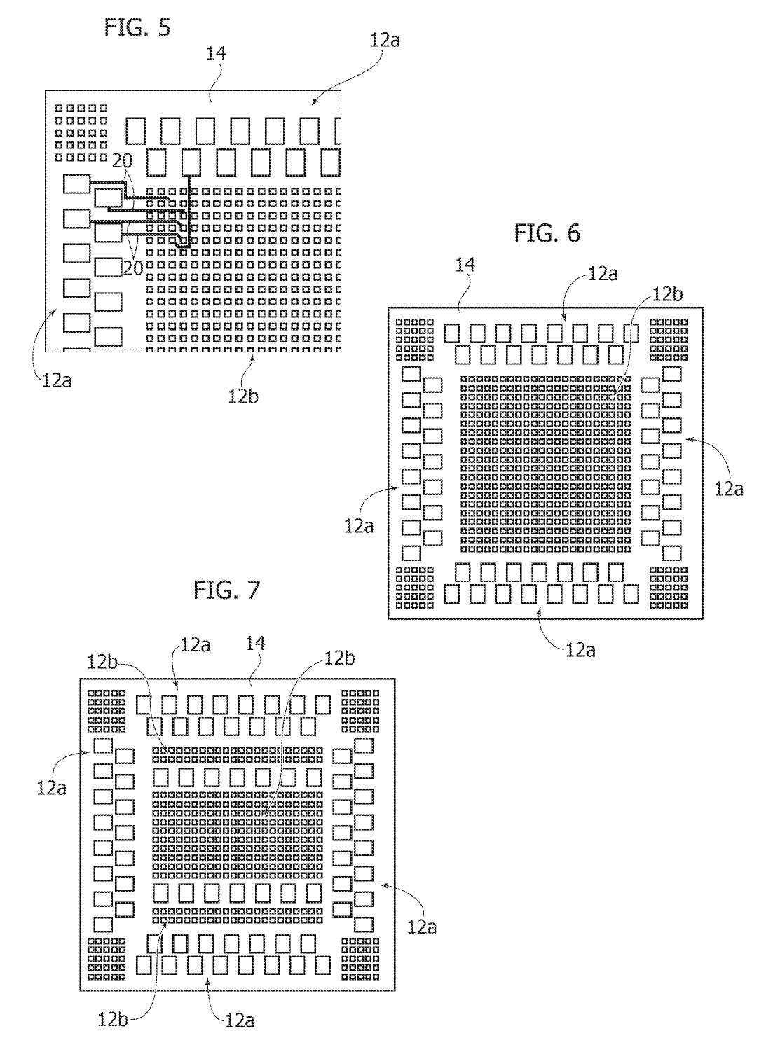

FIGS. 4 and 5 illustrate some schematic examples and possibilities for metal ink printing routing over the arrays 12a, 12b which may be based on specific die requirements e.g. metal track 100-20 micron (100-20.10⁻⁶ m), pitch 50 micron (50.10⁻⁶ m).

FIGS. 6 and 7 illustrate some possible examples of substrate customization. Based e.g. on the product portfolio, die size and I/O requirements, a “universal” substrate design may be defined to comply with a large number of applications.

One or more embodiments as exemplified herein may thus offer one or more of the following advantages:
a same substrate/lead frame may be used for different dice with specific size and a wider range of I/O connections;
flexibility of use;
rapid sampling for testing and prototyping;
routing according to specific requirements is facilitated; and
ball-grid array (BGA) design can be elaborated also on lead frame (LF) packages.

Without prejudice to the underlying principles, the details and embodiments may vary, even significantly, with respect to what has been described by way of example only without departing from the extent of protection.

The extent of protection is defined by the annexed claims.

1. A substrate for mounting semiconductor devices, comprising:
an electrically insulating layer having first and second opposed surfaces, the electrically insulating layer having a thickness between said first and second opposed surfaces, the substrate including first and second electrically conductive lands in said electrically insulating layer, wherein:
said first lands extend through a whole thickness of said electrically insulating layer and are exposed on both the first and second opposed surfaces of the electrically insulating layer, and
said second lands have a thickness less than the thickness of the electrically insulating layer and are exposed only at the first surface of the electrically insulating layer.

2. The substrate of claim 1, wherein said first lands and said second lands are exposed to said first surface of the electrically insulating layer flush therewith.

3. The substrate of claim 1, wherein said first lands include contact pads at said second surface of the electrically insulating layer.

4. The substrate of claim 1, further including electrically conductive lines at the first surface of the electrically insulating layer coupling selected ones of said first lands with selected ones of said second lands.

5. The substrate of claim 4, wherein said electrically conductive lines include printed lines.

6. The substrate of claim 4, wherein said electrically conductive lines include ink jet printed lines.

7. A semiconductor device, including:
a substrate including an electrically insulating layer having first and second opposed surfaces, the electrically insulating layer having a thickness between said first and second opposed surfaces, the substrate including first and second electrically conductive lands in said electrically insulating layer, wherein:
said first lands extend through a whole thickness of said electrically insulating layer and are exposed on both the first and second opposed surfaces of the electrically insulating layer, and
said second lands have a thickness less than the thickness of the electrically insulating layer and are exposed only at the first surface of the electrically insulating layer;
at least one semiconductor die mounted on said first surface of the electrically insulating layer, and
wire bonding electrically coupling said at least one semiconductor die with selected ones of said first and second lands.

8. The semiconductor device of claim 7, wherein said first lands and said second lands are exposed to said first surface of the electrically insulating layer flush therewith.

9. The semiconductor device of claim 7, wherein said first lands include contact pads at said second surface of the electrically insulating layer.

10. The semiconductor device of claim 7, further including electrically conductive lines at the first surface of the electrically insulating layer coupling selected ones of said first lands with selected ones of said second lands.

11. The semiconductor device of claim 10, wherein said electrically conductive lines include printed lines.

12. The semiconductor device of claim 10, wherein said electrically conductive lines include ink jet printed lines.

13. A method, comprising:
etching a first surface of an electrically conductive laminar carrier to produce raised portions corresponding to locations of first lands and produce a recessed surface,
further etching said recessed surface of said laminar carrier to produce indented portions between raised portion corresponding to locations of second lands,
molding onto said first surface of said laminar carrier an electrically insulating molding material that penetrates into said indented portions and covers said recessed surface of said laminar carrier at said raised portions, and
removing said electrically conductive laminar carrier at a second surface opposite the first surface to expose the molding compound which penetrated into said indented portions.

14. The method of claim 13, wherein removing comprises reducing a thickness of the laminar carrier from the second surface.

15. A method, comprising:
growing first and second electrically conductive formations on a first surface of a sacrificial carrier layer, wherein said first electrically conductive formations correspond to locations of first lands, and wherein said second electrically conductive formations correspond to locations of seconds lands,
applying a mask material on said first surface of said sacrificial carrier layer to penetrate into indented portions between said second electrically conductive formations and further covers said second electrically conductive formations while leaving said first electrically conductive formations uncovered,
further growing electrically conductive material onto said uncovered first electrically conductive formations,
molding onto said first surface of said sacrificial carrier layer an electrically insulating molding material that fills space between the further grown electrically conductive material, and
removing the sacrificial carrier layer.
